(19) United States
(12) Patent Application Publication
(10) Pub. No.: US 2025/0113671 A1
(43) Pub. Date: Apr. 3, 2025

(54) LIGHT EMITTING ELEMENT AND LIGHT EMITTING DEVICE

(71) Applicant: NICHIA CORPORATION, Anan-shi, Tokushima (JP)

(72) Inventors: Takeshi KUSUSE, Tokushima-shi (JP); Kentaro WATANABE, Anan-shi (JP)

(73) Assignee: NICHIA CORPORATION, Anan-shi, Tokushima (JP)

(21) Appl. No.: 18/730,830

(22) PCT Filed: Jan. 26, 2023
(86) PCT No.: PCT/JP2023/002511

§ 371 Date: Jul. 22, 2024

(30) Foreign Application Priority Data
Apr. 26, 2022 (JP) 2022-072564

(51) Int. Cl. H10H 20/831; H10H 20/825; H10H 20/854

(52) U.S. Cl. CPC H10H 20/8312; H10H 20/825; H10H 20/854

(57) ABSTRACT

The aim is to provide a light emitting element and a light emitting device that can achieve higher light extraction efficiency. A light emitting element comprises a substrate, a semiconductor structure disposed on the substrate and including successively from the substrate side an n-side semiconductor layer, an active layer, and a p-side semiconductor layer, a p-electrode disposed on and electrically connected to the p-side semiconductor layer, and an n-electrode disposed on and electrically connected to the n-side semiconductor layer. The n-electrode includes a base and a plurality of extended parts extending from the base. The substrate includes an exposed portion exposed from the semiconductor structure, and the exposed portion includes a first exposed portion positioned between two adjacent extended parts and a second exposed portion disposed in the peripheral portion of the substrate and connected to the first exposed portion in a top view. The p-electrode is positioned between the extended parts and the first exposed portion in a top view.

### CROSS-REFERENCE TO RELATED APPLICATIONS

This application is a national stage of PCT Application No. PCT/JP2023/002511, filed on Jan. 26, 2023, which claims priority to Japanese Application No. 2022-072564, filed on Apr. 26, 2022.

### TECHNICAL FIELD

The present invention relates to a light emitting element and a light emitting device.

### BACKGROUND

A light emitting element comprising a semiconductor structure, which has an n-type semiconductor layer, an active layer and p-type semiconductor layer stacked to expose a portion of the n-type semiconductor layer, an n-electrode and a p-electrode provided on the same side of the semiconductor structure has been proposed. In such a light emitting element, nonuniform current diffusion can occur in the semiconductor structure because of the composition of the semiconductor structure. Thus, various efforts have been made to achieve uniform in-plane current density.

For example, a technique has been proposed to control the horizontal current flow with a trench provided between the electrodes that are connected to the semiconductor structure. See, for example, Patent Publication 1.

### CITATION LIST

### Patent Literature

Patent Publication 1: Translation of PTC Patent Application Publication No. 2010-530628

### SUMMARY OF INVENTION

### Technical Problem

The present invention was created in view of the problems described above, and aims to provide a light emitting element and a light emitting device that can achieve higher light extraction efficiently.

### Solution to Problem

The present disclosure includes the invention described below.
(1) A light emitting element comprising:
   a substrate;
   a semiconductor structure disposed on the substrate and including, successively from the substrate side, an n-side semiconductor layer, an active layer, and a p-side semiconductor layer;
   a p-electrode disposed on and electrically connected to the p-side semiconductor layer; and
   an n-electrode disposed on and electrically connected to the n-side semiconductor layer, wherein:
   the n-electrode includes a base and a plurality of extended parts extending from the base;
   the substrate includes an exposed portion exposed from the semiconductor structure,
   in a top view, the exposed portion includes a first exposed portion positioned between two adjacent extended parts, and a second exposed portion provided in the peripheral portion of the substrate and connected to the first exposed portion, and
   in a top view, the p-electrode is provided between the extended parts and the first exposed portion.
(2) A light emitting device comprising the light emitting element described above and a cover member covering the lateral faces of the n-side semiconductor layer and the lateral faces of the active layer that are adjacent to the exposed portion.

### Effect of the Invention

An embodiment of a light emitting element and a light emitting device of the present invention can provide a light emitting element and a light emitting device that can achieve higher light extraction efficiency.

### BRIEF DESCRIPTION OF THE DRAWINGS

FIG. 1 is a plan view schematically showing a light emitting element according to one embodiment of the present disclosure.

FIG. 2 is an end face view taken along line II-II in FIG. 1.

FIG. 3 is a plan view schematically showing a light emitting element according to another embodiment of the present disclosure.

FIG. 4 is a plan view schematically showing a light emitting element according to yet another embodiment of the present disclosure.

FIG. 5 is a plan view schematically showing a light emitting device according to one embodiment of the present disclosure.

FIG. 6 is a cross-sectional view taken along line VI-VI in FIG. 5.

FIG. 7A is a cross-sectional view explaining a method of manufacturing a light emitting element according to one embodiment of the present disclosure.

FIG. 7B is a cross-sectional view explaining the method of manufacturing a light emitting element according to the embodiment of the present disclosure.

FIG. 7C is a cross-sectional view explaining the method of manufacturing a light emitting element according to the embodiment of the present disclosure.

FIG. 7D is a cross-sectional view explaining the method of manufacturing a light emitting element according to the embodiment of the present disclosure.

FIG. 7E is a cross-sectional view explaining the method of manufacturing a light emitting element according to the embodiment of the present disclosure.

FIG. 7F is a cross-sectional view explaining the method of manufacturing a light emitting element according to the embodiment of the present disclosure.

### DETAILED DESCRIPTION

The drawings referenced in the description below schematically illustrate certain embodiments. As such, the scale, spacing, and positional relationship of the members might be exaggerated or a portion of a member omitted in the drawings. Furthermore, the scale or spacing of members might not match between a plan view and a cross-sectional view. In the following description, members that are identical or have similar functions are basically denoted by the same designations or reference numerals for which detailed description might be omitted as appropriate. In the present specification and the drawings, the first direction means the direction that parallels a side of the semiconductor structure 15 that is indicated by the arrow F. Similarly, the second direction means the direction orthogonal to the first direction that is indicated by the arrow S.

### Light Emitting Element 10

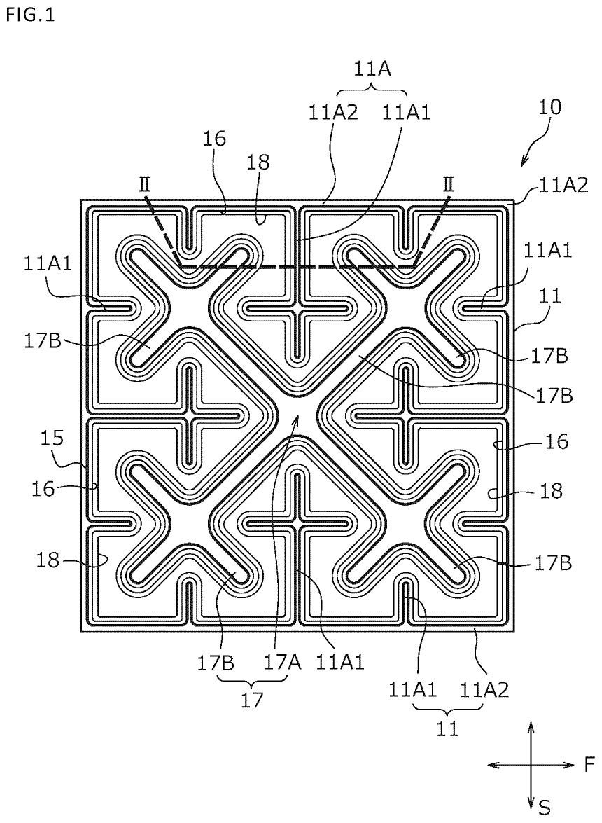

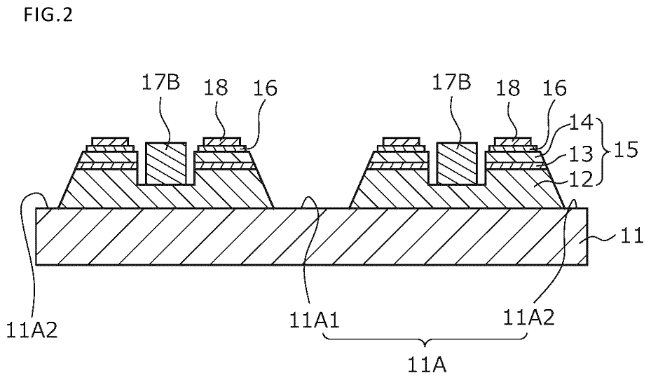

A light emitting element according to one embodiment of the present disclosure, for example, includes a substrate 11, a semiconductor structure 15 which includes successively from the substrate 11 side an n-side semiconductor layer 12, an active layer 13, and a p-side semiconductor layer 14, a p-electrode 16 disposed on and electrically connected to the p-side semiconductor layer 14, and an n-electrode 17 disposed on and electrically connected to the n-side semiconductor layer 12 as shown in FIG. 1 and FIG. 2.

The n-electrode 17 includes a base 17A and multiple extended parts 17B that extend from the base 17A.

The substrate 11 includes an exposed portion 11A exposed from the semiconductor structure 15. In a top view, the exposed portions 11A include a first exposed portion 11A1 provided between two adjacent extended parts 17B and a second exposed portion 11A2 provided in the peripheral portion of the substrate 11 and connected to the first exposed portion 11A1. The p-electrode 16, in a top view, is disposed between the extended parts 17B and the first exposed portion 11A1.

As described above, the light emitting element according to one embodiment of the present disclosure has a first exposed portion 11A1 as an exposed portion 11A of the substrate 11 between two adjacent extended parts 17B. This makes it possible to extract the light emitted by the active layer 13 from the lateral faces of the semiconductor structure 15 more efficiently while reducing the absorption by the semiconductor structure 15 as compared to a light emitting element in which the exposed portion 11A is provided only in the periphery of the semiconductor structure 15. This, as a result, increases the efficiency in extracting light from the light emitting element, achieving a high brightness light emitting element. The first exposed portion 11A1 and the second exposed portion 11A2 being connected makes it easier to place a cover member 21 on the lateral faces of the semiconductor structure 15 in the case of covering the lateral faces of the semiconductor structure 15 with a cover member 21 as described later. Accordingly, the cover member 21 is allowed to reflect the light exiting the lateral faces of the semiconductor structure 15 towards the light extraction face efficiently. This can further improve the light extraction efficiency of the light emitting device.

### Semiconductor Structure 15

A semiconductor structure 15 includes successively from the substrate 11 side an n-side semiconductor layer 12, an active layer 13, and a p-side semiconductor layer 14. The upper face of the n-side semiconductor layer 12 has a region on which the active layer 13 and the p-side semiconductor layer 14 are stacked, and a region on which no active layer 13 or p-side semiconductor layer 14 is present. The upper face of the n-side semiconductor layer 12 has a region that is exposed from the active layer 13 and the p-side semiconductor layer 14. The region of the upper face of the n-side semiconductor layer 12 that is exposed from the active layer 13 and the p-side semiconductor layer 14 will be referred to as an n-layer exposed portion. The n-layer exposed portion is surrounded by the active layer 13 and the p-side semiconductor layer 14 in a plan view. The n-electrode 17 is electrically connected to the n-side semiconductor layer 12 at the n-layer exposed portion.

The shapes, sizes, positions, and number of n-layer exposed portions can be suitably set in accordance with the intended size, shape, and electrode shape of the light emitting element. The shape of an n-layer exposed portion is, for example, a circle, an ellipse, a polygon, such as a triangle, quadrangle, hexagon, or a shape that combines these shapes. The n-layer exposed portion is preferably provided to have a point symmetry about the center of the substrate 11, or a line symmetry using the line that bisects a side of the substrate 11 as the line of symmetry. Electrically connecting the n-electrode 17 to the n-layer exposed portion provided as described above can reduce current density distribution nonuniformity. As a result, the brightness nonuniformity of the light emitting element can be reduced as a whole. In the present specification, “brightness” means “radiance” in the case of a light emitting element that emits ultraviolet or infrared light.

In a plan view, the area of the n-layer exposed portion, for example, is preferably 30% of the total area of the semiconductor structure 15 or less, 25% or less, 20% or less, or 15% or less. Setting the area to fall within such a range can improve the brightness while maintaining the area of the active layer 13.

Various semiconductors can be used for the semiconductor structure 15, including group III-V compound semiconductors, group II-VI compound semiconductors, and the like. Specifically, nitride-based semiconductor materials, for example, In_{X}Al_{Y}Ga_{1-X-Y}N (0≤X, 0≤Y, 0≤X+Y≤1), such as InN, AlN, GaN, InGaN, AlGaN, InGaAlN, or the like, can be used. As for the thickness of each layer, the layer structure, and composition, any of those known in the art can be utilized. The peak wavelength of the light from the light emitting element can be visible light, ultraviolet light, or infrared light. In the case of a light emitting element that emits ultraviolet light, for example, the active layer 13 and the n-side semiconductor layer 12 preferably include a semiconductor layer made of AlGaN with a 30% or higher Al composition ratio. The peak wavelength of the light from the active layer 13 is more preferably in a range of 250 nm to 330 nm. Alight emitting element 10 that emits ultraviolet light can be utilized in applications, such as sterilization, sanitization, and the like.

The outline of the plane shape of the semiconductor structure 15 is, for example, a circle, an ellipse, or a polygon, such as a quadrangle, hexagon, and the like. In a plan view, the outer edge of the semiconductor structure 15 is located inward of the outer edge of the substrate 11.

### Substrate 11

A substrate 11 supports the semiconductor structure 15. An example of the substrate 11 is one that allows for epitaxial growth of the semiconductor layers that make up the semiconductor structure 15. Examples of the substrate 11 include insulation substrates, such as sapphire (Al₂O₃) and spinel (MgAl₂O₄), nitride based semiconductor substrates, such as AlN, GaN, and the like. In the case of using a nitride semiconductor for the semiconductor structure 15, a sapphire substrate having C-plane as a growth face is preferably used. Furthermore, the substrate may have an off-angle of about 0° to 10° relative to C-plane. The substrate 11 may have a number of protrusions on the upper face on which the semiconductor structure 15 is disposed.

Examples of the plane shape of the substrate 11 include, for example, a polygon, such as a rectangle or hexagon, a circle, or an ellipse. A quadrangle, hexagon, or either of them with rounded corners is preferable.

The upper face of the substrate 11 includes an exposed portion 11A that is exposed from the semiconductor structure 15. The exposed portions 11A have a first exposed portion 11A1 located between two adjacent extended parts 17B, and a second exposed portion 11A2 exposed from the semiconductor structure 15 in the peripheral portion of the substrate 11. The second exposed portion 11A2 is a region in which the substrate 11 is exposed between the outer edge of the semiconductor structure 15 and the outer edge of the substrate 11. The first exposed portion 11A1 is connected to the second exposed portion 11A2. The second exposed portion 11A2 may be provided in the peripheral portion of the substrate 11 only in part, but is preferably provided to surround the semiconductor structure 15.

Two or more first exposed portions 11A1 are preferably provided per semiconductor structure 15, and three or more are more preferable. In the case of providing multiple first exposed portions 11A1, all of the first exposed portions 11A1 are preferably connected to the second exposed portion 11A2. This makes it possible to dispose the cover member 21 described later on the lateral faces of the semiconductor structure 15 where the first exposed portions 11A1 are adjacent to the second exposed portion 11A2. This, as a result, allows the cover member 21 to reflect the light exiting the lateral faces of the semiconductor structure 15 towards the light extraction face efficiently, thereby improving the brightness of the light emitting element.

The exposed portions 11A, as shown in FIG. 1, have a second exposed portion 11A2 provided in the peripheral portion of the rectangular substrate 11. The exposed portions 11A have first exposed portions 11A1 that are connected to the second exposed portion 11A2. In FIG. 1, some first exposed portions 11A1 extend along the second direction S from the three positions that divide each side of the substrate 11 paralleling the first direction F into four equal parts. Moreover, other first exposed portions 11A1 extend along the first direction F from the three positions that divide each side of the substrate 11 paralleling the second direction S into four equal parts. Each of the first exposed portions 11A1 that extends along the second direction S from the position that bisects each side of the substrate 11 paralleling the first direction F has a part that extends along the first direction F. Each of the first exposed portions 11A1 that extends along the first direction F from the position that bisects each side of the substrate 11 paralleling the second direction S has a part that extends along the second direction S.

A total of twelve first exposed portions 11A1 that are connected to the second exposed portion 11A2 are provided, three at each side of the substrate 11. The length of each first exposed portion 11A1 is, for example, 5% to 45% of the length of a side of the substrate 11. The exposed portions 11A shown in FIG. 1 are arranged to have a point symmetry about the center of the substrate 11.

The width in the second direction S of a first exposed portion 11A1 that extends in the first direction F and the width in the first direction F of a first exposed portion 11A1 that extends in the second direction S are, for example, 0.2% to 5% of the length of a side of the substrate 11. The width in the second direction S of the second exposed portion 11A2 that extends in the first direction F and the width in the first direction F of the second exposed portion 11A2 that extends in the second direction S are, for example, 0.5% to 10% of the length of a side of the substrate 11. The widths of the first exposed portions 11A1 may be the same or different. The widths of the second exposed portion 11A2 at all locations may be the same or different.

The shapes, sizes, and positions of the exposed portions 11A can be suitably set in accordance with the size, shape, electrode shape of the light emitting element. Furthermore, the shapes, sizes, and positions of the exposed portions 11A can be suitably set in accordance with the size of the semiconductor structure 15, the output and brightness of the light emitting element.

The total area of the exposed portions 11A in a plan view, for example, can be 30% of the total area of the substrate 11 or less, 25% or less, 20% or less, or 15% or less. Setting the area in such a range can improve the brightness while maintaining the area of the active layer 13. Specifically, the area of the first exposed portions 11A1 can be, for example, 0.5% to 10% of the total area of the substrate 11. The area of the second exposed portion 11A2 can be, for example, 1% to 20% of the total area of the substrate 11. Setting their areas in such a range can improve the brightness while maintaining the area of the active layer 13 of the light emitting element 10.

A single semiconductor structure 15 is preferably placed on the substrate 11. A single semiconductor structure 15 means that the semiconductor structure 15 is not separated by the layout of the exposed portions 11A in a plan view.

Regularly positioning the exposed portions 11A can reduce current density distribution nonuniformity in the light emitting element 10. This, as a result, can reduce the brightness nonuniformity of the light emitting element as a whole. Particularly, at least one first exposed portion 11A1 is preferably provided between two extended parts 17B, more preferably, all of the first exposed portions 11A1 are provided between extended parts 17B, as described later. Such an arrangement can further reduce current density distribution nonuniformity, thereby reducing the brightness nonuniformity of the light emitting element as a whole.

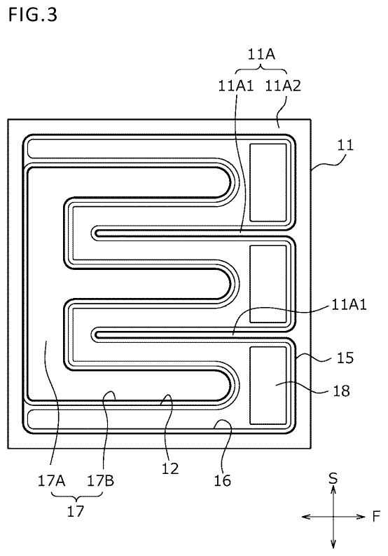

In the light emitting element according to another embodiment of the present disclosure shown in FIG. 3, the exposed portions 11A include two first exposed portions 11A1 extending in the first direction F and a second exposed portion 11A2 located in the peripheral portion of the rectangular substrate 11. The two first exposed portions 11A1 respectively extend in the first direction F from the second exposed portion 11A2 at one third and two thirds of the length of a side of the rectangular substrate 11 that extends along the second direction S. The length of each first exposed portion 11A1 is, for example, 30% to 80% of the length of the side of the substrate 11. The exposed portions 11A shown in FIG. 3 are provided so as to have a line symmetry using the bisector that extends in the first direction F and divides the substrate 11 into two equal parts as the line of symmetry.

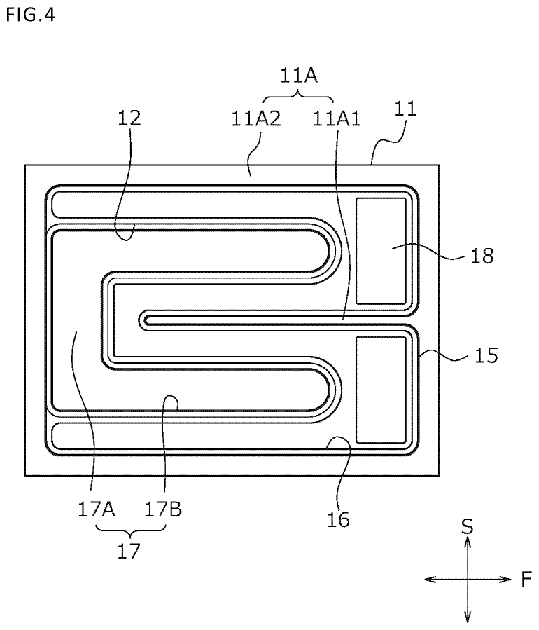

In the light emitting element according to another embodiment of the present disclosure shown in FIG. 4, the exposed portions 11A have a first exposed portion 11A1 that extends in the first direction F and a second exposed portion 11A2 provided in the peripheral portion of the rectangular substrate 11. The first exposed portion 11A1 extends in the first direction F from the second exposed portion 11A2 at the center of a side of the rectangular substrate 11 along the second direction S. The length of the first exposed portion 11A1 is, for example, 40% to 80% of a side of the substrate 11. The exposed portions 11A shown in FIG. 4 are provided to have a line symmetry using the bisector extending in the first direction F and dividing the substrate 11 into two equal parts as the line of symmetry.

In the light emitting element used in the light emitting device according to an embodiment of the present disclosure shown in FIG. 5, the exposed portions 11A include four first exposed portions 11A1 that extend in the first direction F or the second direction S, and a second exposed portion 11A2 provided in the peripheral portion of the rectangular substrate 11. The four first exposed portions 11A1 are respectively extending from the midpoint of each side of the rectangular substrate 11 towards the center of the substrate 11. The length of each first exposed portion 11A1, for example, can be 5% to 45% of the length of a side of the substrate 11. The exposed portions 11A shown in FIG. 5 are arranged to have a point symmetry about the center of the substrate 11.

The first exposed portions 11A1 shown in FIGS. 3, 4, and 5 may each have a portion orthogonally or obliquely intersecting the straight portion thereof, an oblique angle being in a range of 45 to 135 degrees.

### P-Electrode 16 and N-Electrode 17

An n-electrode 17 and a p-electrode 16 are disposed on the upper face side of the semiconductor structure 15.

The p-electrode 16 is disposed on and electrically connected to the p-side semiconductor layer 14. The p-electrode 16 is disposed between the extended parts 17B and the first exposed portions 11A1 in a top view. The p-electrode 16 is preferably provided practically across the entire upper face of the p-side semiconductor layer 14. In a top view, the p-electrode 16 preferably encloses the peripheries of all of the first exposed portions 11A1. The width of the p-electrode 16 located between the extended parts 17B and the first exposed portions 11A1 is preferably 10 μm or larger, more preferably 30 μm to 200 μm. Allowing the p-electrode 16 to have such a width can facilitate electric current diffusion in the p-side semiconductor layer 14 in an efficient manner.

On the upper face of the p-electrode 16, a p-pad electrode 18 that is electrically connected to the p-electrode 16 is disposed. The p-pad electrode 18 may be disposed across the entire upper face of the p-electrode 16, or on a portion of the upper face of the p-electrode 16.

The n-electrode 17 is disposed on the n-layer exposed portion where the n-side semiconductor layer 12 is exposed form the active layer 13 and the p-side semiconductor layer 14, and electrically connected to the n-side semiconductor layer 12.

The n-electrode 17 includes a base 17A and extended parts 17B that extend from the base 17A.

The shape and the size of the base 17A can be suitably set in accordance with the shapes and sizes of the semiconductor structure 15, the first exposed portions 11A1 and the second exposed portion 11A2 of the substrate 11. The base 17A can have various shapes in a plan view, such as a polygon, a polygonal shape with rounded corners, and the like.

The extended parts 17B extend in different directions from multiple positions of the base 17A.

For example, the base 17A is positioned in the central portion of the semiconductor structure 15 in a plan view as shown in FIG. 1. The extended parts 17B extend from the base 17A towards the four corners of the substrate 11. The extended parts 17B may each have a shape having one straight part, or a shape having a straight part and a part that extends from the straight part. The direction in which a part extends from the straight part is not limited to one direction, and can be two or more, or three or more directions. An example of the direction of a part that extends from the straight part is 45 to 90 degree oblique to the straight part. In FIG. 1, an extended part 17B extending from the base 17A has a straight part and a part that is orthogonal to and extending from the straight part in two directions. The extended parts 17B respectively extend from four positions of the base 17A. In a top view, the n-electrode 17 shown in FIG. 1 is provided to have a point symmetry about the center of the substrate 11.

In the light emitting element according to the embodiment of the present disclosure shown in FIG. 3, the n-electrode 17 has a base 17A that is adjacent to a side that extends in the second direction S. The n-electrode 17 has multiple extended parts 17B each being straight and extending in the first direction F. Each extended part 17B may have a shape that has a straight part, or a shape that has a straight part and a part that extends from the straight part. For example, the three extended parts 17B are parallel to one another and extend from the two end portions and the central portion of the base 17A. The three extended parts 17B may have different widths and lengths from one another, but preferably have the same widths and lengths. The n-electrode 17 is provided to have a line symmetry using the bisector extending in the first direction F and dividing the substrate 11 into two equal parts as the line of symmetry.

In the light emitting element according to the embodiment of the present disclosure shown in FIG. 4, the n-electrode 17 has a base 17A that is adjacent to a side that extends in the second direction S. The n-electrode 17 has multiple extended parts 17B each having a straight shape and extending in the first direction F. The extended parts 17B may each have a shape having a straight part, or a shape having a straight part and a part that extends from the straight part. For example, the two extended parts 17B paralleling one another extend from both end portions of the base 17A. The two extended parts 17B may have different widths and lengths from one another, but preferably have the same widths and lengths. The n-electrode 17 is provided to have a line symmetry using the bisector extending in the first direction F and dividing the substrate 11 into two equal parts as the line of symmetry.

In any of the shapes of the base 17A and the extended parts 17B described above, it is preferable to position at least one first exposed portion 11A1 between two extended parts 17B, and is more preferable to position all of the first exposed portions 11A1 between the extended parts 17B.

The n-electrode 17, the p-electrode 16, and the p-pad electrode 18 can be, for example, a single layer or multilayer structure that includes a metal, such as Au, Pt, Pd, Rh, Ru, Ni, W, Mo, Cr, Ti, Al, Cu, Ta, Si, or their alloys. Specifically, the p-electrode 16 can be a multilayer structure, such as Rh/Ni/Au, Ru/Ni/Au, or the like. Specifically, the n-electrode 17 and the p-pad electrode 18 can be a multilayer structure made by successively stacking these metals from the semiconductor structure 15 side, such as Ti/Rh/Au, Ti/Pt/Au, W/Pt/Au, Rh/Pt/Au, Ni/Pt/Au, Ti/Ru/Ti, Ti/Al-Si/Ta/Ru, or the like. For example, “Ti/Rh/Au” stacked successively from the semiconductor structure 15 side means that Ti, Rh, and Au are stacked successively from the semiconductor structure 15 side. The n-electrode 17, the p-electrode 16, and the p-pad electrode 18 can each have any film thickness used in the art.

### Light Emitting Device 20

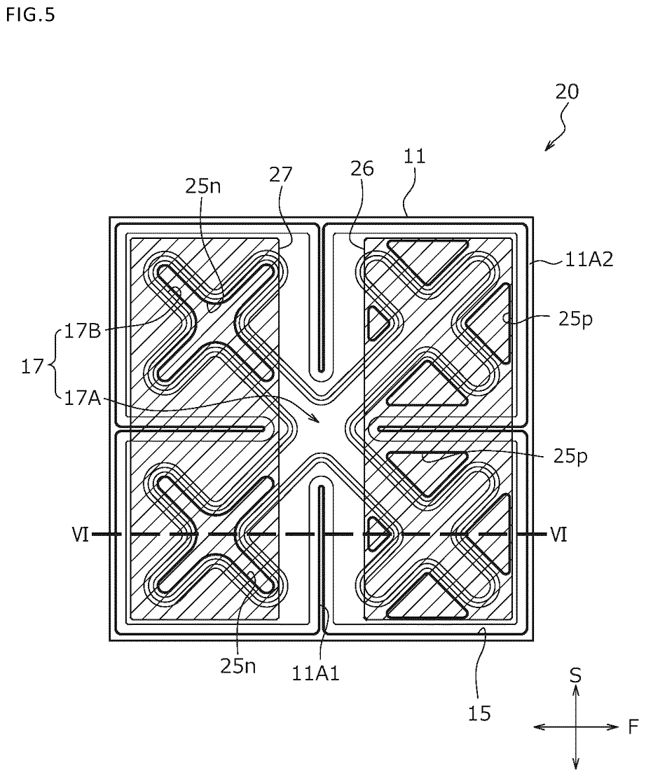

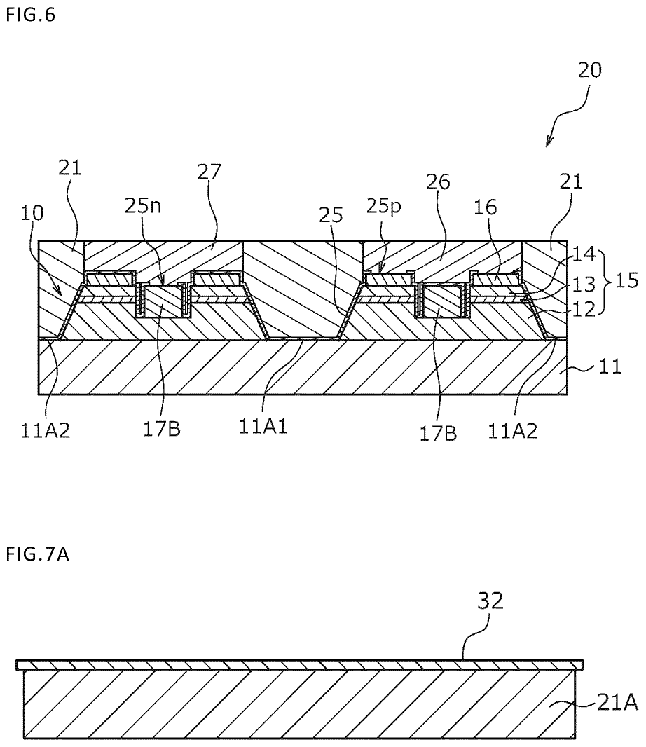

A light emitting device 20 according to an embodiment of the present disclosure, for example, includes the light emitting element 10 described above and a cover member 21 as shown in FIG. 6.

The light emitting device 20, as shown in FIGS. 5 and 6, has a p-side external connection part 26 that is electrically connected to the p-electrode 16 and an n-side external connection part 27 that is electrically connected to the n-electrode 17. A portion of the p-side external connection part 26 and a portion of the n-side external connection part 27 are exposed from the cover member 21. Such a structure allows for flip-chip mounting of the light emitting device 20.

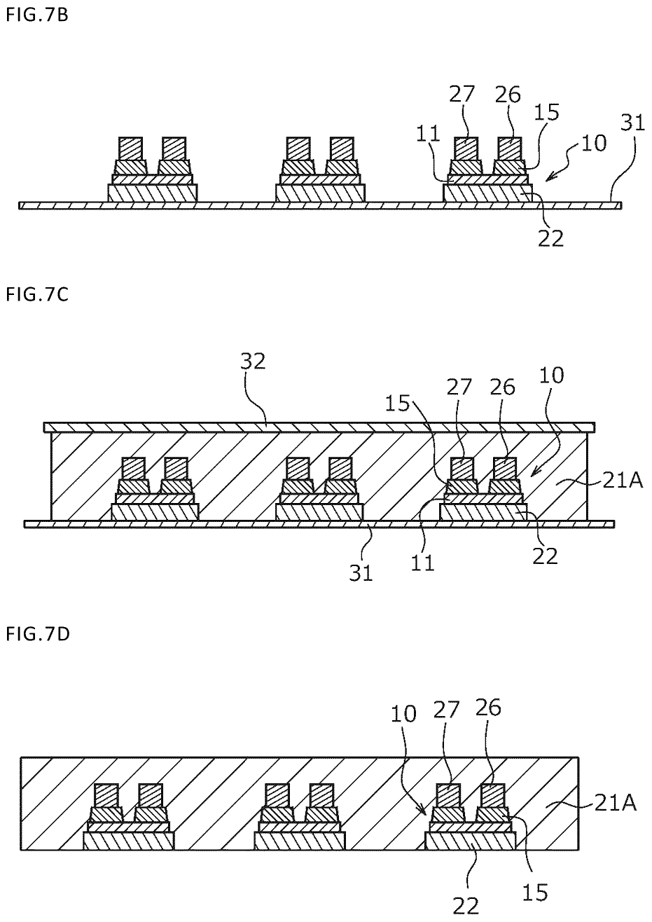

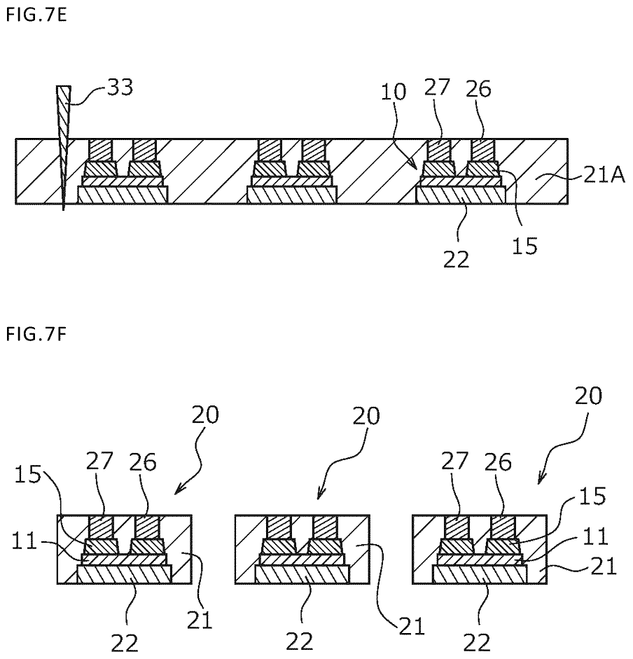

The light emitting device 20, as shown in FIG. 7F, may include a light transmissive member 22 disposed on the substrate 11 of the light emitting element. In this case, the lateral faces of the substrate 11 and the lateral faces of the light transmissive member 22 are preferably covered by the cover member 21.

### Cover Member 21

A cover member 21 covers at least the lateral faces of the n-side semiconductor layer 12 and the lateral faces of the active layer 13 that are adjacent to the exposed portions 11A. The cover member 21 preferably further covers the lateral faces of the p-side semiconductor layer 14, more preferably covers the lateral faces of the p-side external connection part 26 and the lateral faces of the n-side external connection part 27. In the case in which the light emitting element 10 is provided with a light transmissive member 22, it is more preferable for the cover member 21 to further cover the lateral faces of the light transmissive member 22. Here, “covering” includes not only the case in which the cover member 21 covers in contact with the light emitting element 10 and/or the light transmissive member 22, but also the case in which another member, space (air layer), or the like is interposed between the cover member 21 and the light emitting element 10 and/or the light transmissive member 22. The upper face of the light transmissive member 22 exposed from the cover member 21 becomes the emission face of the light emitting device.

The cover member 21 can be composed, for example, of a light transmissive material and a light absorbing material and/or light reflecting material contained therein. The light transmissive material can be an organic material, inorganic material, or the like.

For the organic material, a resin containing a light reflecting substance, phosphor, diffusing material, coloring agent, or the like, can be used. For the resin and the light reflecting substance, any of those normally used in the art can be employed. Examples of resins include those containing one or more of silicone, modified silicone, epoxy, modified epoxy, and acrylic resins, or hybrid resins. Examples of light reflecting substances include silica, titanium oxide, zirconium oxide, potassium titanate, alumina, aluminum nitride, boron nitride, mullite, and the like. The amounts of reflection and transmission of light can be varied by the content of the light reflecting substance or the like contained in the materials that compose the cover member 21. The light reflecting substance content of the cover member 21, for example, is preferably 20 wt % or higher.

The light transmissive material is preferably an inorganic material, more preferably the light transmissive material and the light reflecting substance are both inorganic materials. In other words, the main components of the cover member 21 are preferably inorganic materials. Main components here means those make up 50% by weight or more of the cover member. In this case, the cover member 21 is more preferably constructed with multiple inorganic materials. For example, the cover member 21 can contain a light reflecting material and a support material that supports the light reflecting material. The support material preferably contains silica and an alkali metal. The cover member 21 may further contain a scattering material.

Covering the semiconductor structure 15 and the exposed portions 11A of the substrate with such a cover member 21 allows the cover member 21 to reflect the light exiting the semiconductor structure 15 positioned near the first exposed portions 11A1 towards the light extraction face more effectively. This can produce a light emitting device having a high light extraction efficiency. Particularly, by disposing the cover member 21 on the first exposed portions 11A1 in the semiconductor structure 15, the light exiting the semiconductor structure 15 near the first exposed portions 11A1 can be more effectively reflected towards the light extraction face. In the case of composing the cover member 21 only with inorganic materials, the degradation of the cover member 21 can be reduced even when the light emitted from the light emitting device 20 is ultraviolet light. This can extend the service life of the light emitting device 20.

### Light Reflecting Material

The light reflecting material has only to be capable of reflecting the light from the light emitting element 10, and can be a ceramic material, such as boron nitride or alumina. For the light reflecting material, a sheet shaped, flaky, or granular one is preferably used. The light reflecting material may be either primary or secondary grains. The average grain size of the light reflecting material is, for example, 0.1 μm to 100 μm. One having an average grain size of 0.6 μm to 43 μm is preferably used. The average aspect ratio of the grains for the light reflecting material is, for example, 10 or higher, and is preferably in a range of 10 to 70. The average aspect ratio is represented by the ratio of the largest diameter to the shortest diameter of a particle. Here, the average particle size can be obtained by observing a cross section by using an SEM, measuring the particle size distribution by laser diffraction, or the like.

A light reflecting material having such an average particle size and an average aspect ratio can function as an aggregate for the cover member 21 when heated by the heat generated by the light emitting element 10. This can reduce the contraction of the cover member 21 attributable to the heat from the light emitting element 10, thereby achieving a highly heat resistant light emitting device. Such a light emitting device has a long service life. The cover member 21, moreover, can reflect the light from the light emitting element by utilizing the refractive index difference between those of the light reflecting material and the support material. Furthermore, such a cover member 21 with reduced contraction attributable to the heat from the light emitting element 10 allows for the use of the light emitting device under the conditions where the light emitting element generates a large amount heat (e.g., a large amount of electric power is applied to the light emitting element). Being able to increase the amount of electric power supplied to the light emitting element can increase the brightness per light emitting device.

### Support Material

The support material supports the light reflecting material contained in the cover member 21 to improve the strength of the cover member 21. The mass ratio of the support material to the light reflecting material in the cover member 21 is, for example, 1:4 to 1:1. Setting the ratio in these ranges can reduce the contraction of the cover member when it is hardened. In the case of using silica as the support material, the average particle size of the silica, for example, is 0.1 μm to 10 μm. Setting it in this range can increase the density per volume of the light reflecting material and the support material, thereby enhancing the strength of the cover member. The average particle size of the silica powder is preferably smaller than the average particle size of the light reflecting material. This allows the silica power used as the support material to fill the gaps between the particles of the light reflecting material during mixing. The average particle size of the support material powder is a value measured prior to mixing with a solution containing an alkali metal. The content ratio of the support material to the light reflecting material can be calculated from the cover member, for example, based on the areas occupied by the support material and the light reflecting material observed in a cross section extracted by an SEM.

Examples of alkali metals include potassium, sodium, and the like. Alkali metals are preferably mixed with silica in the state of a solution.

Examples of scattering materials include zirconia, titania, those to which surface treatment is applied using silica, alumina, zirconia, zinc, or an organic material, and stabilized or partially stabilized zirconia to which calcium, magnesium, yttrium, aluminum, or the like is added. In the case in which the light emitting element emits ultraviolet light, zirconia which barely absorbs light in the ultraviolet wavelength region is preferably used. Including a scattering material in the cover member 21 can increase the reflectance of the cover member 21. The scattering material preferably has a smaller average particle size than the average particle size of the light reflecting material. This can easily position the scattering material in the gaps between light reflecting material particles, thereby reducing the amount of the light emitted by the light emitting element 10 that exits the light emitting device via the gaps in the light reflecting material. As a result, the light extraction efficiency of the light emitting device can be improved. The average particle size of the scattering material can be measured by laser diffraction. In the case of adding a scattering material to the cover member 21, the scattering material is preferably dispersed in the support material.

The cover member 21 preferably has a linear expansion coefficient of 0.5 ppm/° C. to 5 ppm/° C. in the temperature range of 40° C. to 300° C. This can reduce the expansion of the cover member 21 even when the temperature of the cover member 21 increased during the operation of the light emitting device.

### P-Side External Connection Part 26 and N-Side External Connection Part 27

A p-side external connection part 26 is electrically connected to the p-electrode 16, and an n-side external connection part 27 is electrically connected to the n-electrode 17. The p-side external connection part 26 and the n-side external connection part 27 are electrically connected to the conducting wires, for example, when the light emitting device 20 is installed. The p-side external connection part 26 and the n-side external connection part 27 can be respectively disposed in two bisected regions of the semiconductor structure 15 having equal areas in a top view. In this case, they are preferably disposed to have a line symmetry using the bisector that divides the area of the semiconductor structure 15 into two areas as the line of symmetry. The p-side external connection part 26 and the n-side external connection part 27 are disposed above the n-side semiconductor layer 12 and the p-side semiconductor layer 14, respectively, via an insulation film 25.

The sizes and the shapes of the p-side external connection part 26 and the n-side external connection part 27 can be suitably set in accordance with the intended performance of the light emitting device.

For the p-side external connection part 26 and the n-side external connection part 27, a single layer or multilayer structure of a metal, such as Cu, Au, Ni, or an alloy of these metals, can be used. The thicknesses of the p-side external connection part 26 and the n-side external connection part 27 are, for example, 1 μm to 50 μm, preferably 10 μm to 30 μm.

### Insulation Film 25

An insulation film 25 covers the upper face and the lateral faces of the semiconductor structure 15. The insulation film 25 has a p-side opening 25p above the p-electrode 16 in the region in which the p-side external connection part 26 is provided, and an n-side opening 25n above the n-electrode 17 in the region in which the n-side external connection part 27 is provided. In the example shown in FIG. 5, the n-side openings 25n are positioned to overlap the extended parts 17B of the n-electrode 17. The p-side external connection part 26 is electrically connected to the p-electrode 16 at the p-side opening 25p. The n-side external connection part 27 is electrically connected to the n-electrode 17 at the n-side openings 25n. In the case in which the insulation film 25 covers the upper face of the semiconductor structure 15 as described above, the n-side external connection part 27 can be disposed on the upper face of the insulation film 25 that covers the upper face of the p-side semiconductor layer 14. Similarly, when the insulation film 25 covers the upper face of the semiconductor structure 15, the p-side external connection part 26 can be disposed on the upper face of the insulation film 25 that covers the upper face of the n-side semiconductor layer 12.

The insulation film 25 is preferably made of a material having light transmissivity, electrical insulation property, and thickness, by using any material known in the art. Specifically, the insulation film 25 can be composed of a metal oxide or metal nitride, for example, an oxide or nitride of at least one selected among the group consisting of Si, Ti, Zr, Nb, Ta, and Al. The insulation film has only to have a thickness that can achieve light transmissivity and insulation property.

### Light Transmissive Member 22

The light emitting device preferably has a light transmissive member 22 on the substrate 11 of the light emitting element 10. The light transmissive member 22 is disposed to cover the light extraction face of the light emitting element 10. The light transmissive member 22 is a member capable of transmitting 50% or more or 60% or more, preferably 70% or more of the light from the light emitting element 10 to be externally output. The light transmissive member 22 can contain a phosphor that can convert the wavelength of at least a portion of the outgoing light from the light emitting element 10. The light transmissive member 22 may contain a light diffusing material that diffuses the outgoing light from the light emitting element 10. The light transmissive member 22 is preferably sheet shaped and has a thickness, for example, in a range of 50 μm to 300 μm.

The light transmissive member 22 can be composed of a resin, glass, inorganic material, or the like, for example. The light transmissive member 22 containing a phosphor can be, for example, a sintered body of a phosphor, a resin, glass or another inorganic material that contains a phosphor. It may be a sheet shaped formed body of a resin, glass, or inorganic material on which a resin layer containing a phosphor is applied. This can produce a high heat resistance light emitting device because a light transmissive member 22 made of an inorganic material has higher heat resistance than one containing a resin. In the case of a light transmissive member 22 not containing a wavelength conversion material, the light from the light emitting element is externally output without undergoing wavelength conversion.

For the phosphor to be included in the light transmissive member 22, yttrium aluminum garnet based phosphors (e.g., Y₃(Al,Ga)₅O₁₂:Ce), lutetium aluminum garnet based phosphors (e.g., Lu₃(Al,Ga)₅O₁₂:Ce), terbium aluminum garnet based phosphors (e.g., Tb₃(Al,Ga)₅O₁₂:Ce), CCA-based phosphors (e.g., Ca₁₀(PO₄)₆Cl₂:Eu), SAE based phosphors (e.g., Sr₄Al₁₄O₂₅:Eu), chlorosilicate based phosphors (e.g., Ca₈MgSi₄O₁₆Cl₂:Eu), oxynitride based phosphors, nitride based phosphors, fluoride based phosphors, phosphors having a Perovskite structure (e.g., CsPb(F,Cl,Br,I)₃), quantum dot phosphors (e.g., CdSe, InP, AgInS₂ or AgInSe₂), or the like can be used. Examples of oxynitride based phosphors include β-SiAlON phosphors (e.g., (Si,Al)₃(O,N)₄:Eu) and α-SiAlON phosphors (e.g., Ca(Si,Al)₁₂(O,N)₁₆:Eu). Examples of nitride based phosphors include SLA-based phosphors (e.g., SrLiAl₃N₄:Eu), CASN-based phosphors (e.g., CaAlSiN₃:Eu), and SCASN-based phosphors (e.g., (Sr,Ca)AlSiN₃:Eu). Examples of fluoride based phosphors include KSF-based phosphors (e.g., K₂SiF₆:Mn), KSAF-based phosphors (e.g., K₂Si_{0.99},Al_{0.01}F_{5.99}:Mn), and MGF-based phosphors (e.g., 3.5MgO·0.5MgF₂·GeO₂:Mn). Combining these phosphors and a blue light emitting element or ultraviolet light emitting element can produce a light emitting device that emits light of a desired color. In the case of including such a phosphor in the light transmissive member 22, the phosphor content is preferably set to 5 wt % to 50 wt %, for example.

The light transmissive member 22 is disposed to cover the light extraction face of the light emitting element 10. The light transmissive member 22 and the light emitting element 10 can be bonded via a bonding material or by direct bonding. For the bonding material, for example, those employing a light transmissive resin, such as an epoxy or silicone resin, can be used.

A cover layer may be disposed on the upper face of the light transmissive member 22 for the purpose of protecting the light transmissive member 22, reducing reflection, or the like. An example of a cover layer is AR (antireflection) layer.

### Method of Manufacturing Light Emitting Device

The light emitting device described above can be manufactured by preparing a light emitting element 10, preparing a sheet shaped cover member 21A, placing the cover member 21A on the substrate 11 of the light emitting element 10 on the semiconductor structure 15 side, and forming the cover member 21A while applying vibration to the lateral faces of the semiconductor structure 15 of the light emitting element 10.

The cover member 21 is preferably hardened by heating after being placed on the lateral faces of the light emitting element 10. Hardening is preferably performed in two stages: preliminary hardening and full hardening. This can reduce the generation of cracks in the cover member 21 when formed. Preliminary hardening can be performed at a temperature in a range of 80° C. to 100° C. for 10 minutes to 2 hours, for example. Full hardening can be performed at a temperature in a range of 150° C. to 250° C. for 10 minutes to 3 hours, for example. Hardening is preferably performed while applying pressure. The pressure applied in this case can be 0.5 MPa to 5 MPa, for example, 1 MPa. This allows the light reflecting material in the cover member to harden in a more densely populated state to thereby increase the reflectance of the cover member 21 when formed. The pressure applied during preliminary hardening and full hardening may be the same or different.

The light emitting element 10 may be prepared one by one, or multiple light emitting elements 10 and multiple light emitting devices may be prepared in a block to be divided into individual light emitting devices 20 after forming a cover member 21A.

First, as shown in FIG. 7A, a sheet shaped cover member 21A is prepared.

The sheet shaped cover member 21A can be formed as described below, for example.

A mixture of light reflecting material powder, silica powder which is a support material, and an alkali solution is prepared. A scattering material may be mixed into this mixture. After mixing the materials to uniform viscosity, the mixture is defoamed and agitated in an agitator defoaming machine which allows for agitation under reduced pressure. Subsequently, the mixture is applied onto a detachable base 32 to be formed as a sheet.

As shown in FIG. 7B, multiple light emitting elements 10 and a light transmissive member 22 placed on the upper faces thereof are prepared. The light transmissive member 22 contains a phosphor. In the case of bonding the light transmissive member 22 and the light emitting elements 10, direct bonding methods, such as surface activated bonding, atomic diffusion bonding, or hydroxyl group bonding, may be used. The light emitting elements 10 are preferably arranged at certain intervals before adhering the light transmissive member 22 to a pressure sensitive adhesive sheet 31.

Then, as shown in FIG. 7C, by placing the sheet shaped cover member 21A and pressing onto the side of each light emitting element 10 on which the p-side external connection part 26 and the n-side external connection part 27 are disposed, the cover member 21A is pushed in so as to be placed on the lateral faces of the light emitting elements 10. The p-side external connection part 26 and the n-side external connection part 27 of each light emitting element 10 are thus covered by the cover member 21A. Because the first exposed portions 11A1 and the second exposed portion 11A2 are connected, the cover member 21A can be easily disposed on the lateral faces of the semiconductor structure 15 that are adjacent to the first exposed portions 11A1. Applying vibration while forming the cover member 21A can increase the fluidity of the cover member 21A, making it easy to form the cover member 21A on the lateral faces of the light emitting elements 10. Furthermore, forming the cover member 21A using a vacuum can reduce the generation of gaps between the light emitting elements 10 and the cover member 21A.

Subsequently, the cover member 21A is preliminarily hardened by applying 1 MPa pressure at 90° C., for example, followed by removing the base 32 from the cover member 21A as shown in FIG. 7D. Then the cover member 21A is fully hardened by applying 1 MPa pressure at 200° C., followed by removing the pressure sensitive adhesive sheet 31 from the light emitting elements.

Then, as shown in FIG. 7E, the upper faces of the p-side external connection parts 26 and the n-side external connection parts 27 are exposed from the cover member 21A by grinding the cover member 21A. This is followed by cutting the cover member 21A between the light emitting elements 10 to obtain the light emitting devices 20 as shown in FIG. 7F. A blade 33 can be used, for example, to cut the cover member 21A.

The method of manufacturing a light emitting device described above can manufacture light emitting devices with improved efficiency in extracting light from the lateral faces of the semiconductor structures 15 adjacent to the first exposed portions 11A1 in an efficient manner. Particularly, the first exposed portions 11A1 and the second exposed portion 11A2 of the substrate 11 being connected makes it easier to dispose a cover member 21 on the lateral faces of the semiconductor structure 15. As a result, the light exiting the lateral faces of the semiconductor structure 15 can be reflected towards the light extraction face efficiently, thereby achieving a higher brightness light emitting device.

The present specification includes the clauses described below.
1. Alight emitting element comprising:
a substrate;
a semiconductor structure disposed on the substrate and including successively from the substrate side an n-side semiconductor layer, an active layer, and a p-side semiconductor layer;
a p-electrode disposed on and electrically connected to the p-side semiconductor layer; and
an n-electrode disposed on and electrically connected to the n-side semiconductor layer, wherein:
the n-electrode includes a base and a plurality of extended parts extending from the base;
the substrate includes an exposed portion exposed from the semiconductor structure;
the exposed portion includes a first exposed portion positioned between two adjacent extended parts and a second exposed portion disposed in the peripheral portion of the substrate and connected to the first exposed portion in a top view; and
the p-electrode is positioned between the extended parts and the first exposed portion in a top view.
2. The light emitting element according to clause 1 wherein:
the n-electrode includes three or more extended parts; and
the first exposed portions are individually provided between two adjacent extended parts.
3. The light emitting element according to clause 1 or 2 wherein the second exposed portion surrounds the semiconductor structure in a top view.
4. The light emitting element according to any one of clauses 1 to 3 wherein the semiconductor structure is singular.
5. The light emitting element according to any one of clauses 1 to 4 wherein the active layer and the n-side semiconductor layer include a semiconductor layer made of AlGaN having an Al composition ratio of 30% or higher.
6. The light emitting element according to any one of clauses 1 to 5 wherein the peak emission wavelength of the light from the active layer is 250 nm to 330 nm.
7. Alight emitting device comprising:
   a light emitting element according to any one of clauses 1 to 6; and
   a cover member covering at least the lateral faces of the n-side semiconductor layer and the lateral faces of the active layer that are adjacent to the exposed portion in a top view.
8. The light emitting device according to clause 7 wherein the main component of the cover member is an inorganic material.

### REFERENCE NUMERALS

10 light emitting element
11 substrate
   11A exposed portion
      11A1 first exposed portion
      11A2 second exposed portion
12 n-side semiconductor layer
13 active layer
14 p-side semiconductor layer
15 semiconductor structure
16 p-electrode
17 n-electrode
   17A base
   17B extended part
18 p-pad electrode
20 light emitting device
21, 21A cover member
22 light transmissive member
25 insulation film
   25n n-side opening
   25p p-side opening
26 p-side external connection part
27 n-side external connection part
31 pressure sensitive adhesive sheet
32 base
33 blade

1. A light emitting element comprising:
a substrate;
a semiconductor structure disposed on the substrate and including successively from the substrate side an n-side semiconductor layer, an active layer, and a p-side semiconductor layer;
a p-electrode disposed on and electrically connected to the p-side semiconductor layer; and
an n-electrode disposed on and electrically connected to the n-side semiconductor layer, wherein:
the n-electrode includes a base and a plurality of extended parts extending from the base;
the substrate includes an exposed portion exposed from the semiconductor structure;
the exposed portion includes a first exposed portion positioned between two adjacent extended parts and a second exposed portion disposed in the peripheral portion of the substrate and connected to the first exposed portion in a top view; and
the p-electrode is positioned between the extended parts and the first exposed portion in a top view.

2. The light emitting element according to claim 1, wherein:
the n-electrode includes three or more extended parts; and
the first exposed portions are individually provided between two adjacent extended parts.

3. The light emitting element according to claim 1, wherein the second exposed portion surrounds the semiconductor structure in a top view.

4. The light emitting element according to claim 1, wherein the semiconductor structure is singular.

5. The light emitting element according to claim 1, wherein the active layer and the n-side semiconductor layer include a semiconductor layer made of AlGaN having an Al composition ratio of 30% or higher.

6. The light emitting element according to claim 1, wherein the peak emission wavelength of the light from the active layer is 250 nm to 330 nm.

7. A light emitting device comprising:
a light emitting element according to claim 1; and
a cover member covering at least the lateral faces of the n-side semiconductor layer and the lateral faces of the active layer that are adjacent to the exposed portion in a top view.

8. The light emitting device according to claim 7, wherein the main component of the cover member is an inorganic material.
